(19) United States
(12) Patent Application Publication
(10) Pub. No.: US 2026/0334115 A1
(43) Pub. Date: Oct. 22, 2026

(54) ION IMPLANTATION METHOD

(71) Applicant: Shanghai Huali Integrated Circuit Corporation, Shanghai (CN)

(72) Inventors: Yang LIU, Shanghai (CN); Li ZHANG, Shanghai (CN); Wei XIE, Shanghai (CN)

(73) Assignee: Shanghai Huali Integrated Circuit Corporation, Shanghai (CN)

(21) Appl. No.: 19/647,275

(22) Filed: Apr. 14, 2026

(30) Foreign Application Priority Data
Apr. 18, 2025 (CN) 202510499306.4

(51) Int. Cl. H10P 30/20; H10P 30/22

(52) U.S. Cl. CPC H10P 30/226; H10P 30/212; H10P 30/22

(57) ABSTRACT

This application discloses an ion implantation method. The method includes: defining a formation region of an ion implantation region, where an implantation dose required for the ion implantation region is a first implantation dose; performing first ion implantation at a temperature lower than room temperature, an implantation dose is a second implantation dose, the second implantation dose is a part of the first implantation dose, and an implantation energy for the first ion implantation defines a bottom interface of the ion implantation region; and performing a second ion implantation, where a temperature for the second ion implantation is higher than the temperature for the first ion implantation, an implantation dose is a third implantation dose, the third implantation dose is the first implantation dose minus the second implantation dose, and an implantation energy for the second ion implantation is less than the implantation energy for the first ion implantation.

### CROSS-REFERENCES TO RELATED APPLICATIONS

This application claims priority to Chinese patent application No. 202510499306.4, filed on Apr. 18, 2025, the disclosure of which is incorporated herein by reference in its entirety.

### TECHNICAL FIELD

This application relates to a method for manufacturing a semiconductor integrated circuit, and in particular, to an ion implantation method.

### BACKGROUND

Compared with room temperature ion implantation, cold ion implantation (IMP) may significantly improve an ion implantation interface. An interface formed under the cold ion implantation is denser, which can reduce device leakage. Therefore, compared with the room temperature implant, cold germanium (Ge) ion implantation improves a doping distribution morphology, thereby improving performance of NMOS (N-channel metal oxide semiconductor) devices.

However, after a room temperature is changed to a low temperature, new problems occur in cold ion implantation. The new problems are frequent walking-out alarms of ion implantation machines. Walking out brings serious product defects that cannot be completely removed or causes scrapped wafers, which seriously affects a yield and product safety.

The temperature for cold ion implantation is low, for example, minus 60 degrees, and a material of a back of a wafer subjected to ion implantation is silicon nitride. Therefore, with a photoresist during ion implantation, an adhesive is easily generated on a surface of a platen for placing a wafer in an ion implantation machine. Viscosity is increased with an increase in a using time, causing a phenomenon of adhered wafers on the platen. After operations are completed, a position of a wafer shifts during removal, so that walking out is generated. Due to positional shifts generated for the wafer, it is easy to contact fixed points such as a frame of a wafer placement slot of a wafer box during a process of transferring the wafer back to the wafer box after ion implantation is completed, thereby causing severe defects.

Referring to FIG. 1, it is a schematic diagram when walking out occurs in an existing cold ion implantation method. A platen 101 is provided with a plurality of pins 103. After ion implantation is completed for a wafer 102, the wafer needs to be removed and is finally transferred back to the wafer box. During the removal, first, the wafer 102 is raised through the pins 103, and then the wafer 102 is removed through a robot arm extending into an ion implantation cavity. In a process of raising the wafer 102 through the pin 103, since an adhesive force generated through the platen 101 is relatively large, a force applied to the wafer 102 is uneven to generate shift. FIG. 1 is a schematic diagram when the wafer 102 in a shifted state. After the wafer 102 is shifted, it is easy to contact or even collide with a fixed point of a machine in a subsequent process of transferring the wafer 102 by the robot arm, so that defects are easily generated, and even wafer dropping or wafer breaking occurs, thereby affecting a yield of a product. When wafer dropping or wafer breaking occurs, a shutdown is also needed for maintenance and cleaning, which reduces uptime of an ion host machine and thus affects a production capacity.

### BRIEF SUMMARY

According to some embodiments in this application, an ion implantation method is disclosed in the following steps:
forming a photoresist pattern on a semiconductor substrate to define a formation region of an ion implant region, where an implantation dose required by the ion implantation region is a first implantation dose;
performing first ion implantation, where a temperature for the first ion implant is lower than a room temperature, an implantation dose for the first ion implantation is a second implantation dose, the second implantation dose is a part of the first implantation dose, and an implantation energy for the first ion implantation defines a bottom interface of the ion implantation region; and
performing a second ion implantation, wherein a temperature for the second ion implantation is higher than the temperature for the first ion implantation, an implantation dose for the second ion implantation is a third implantation dose, the third implantation dose is the first implantation dose minus the second implantation dose, and an implantation energy for the second ion implantation is less than the implantation energy for the first ion implantation.

In some cases, a lowest value of the temperature for the first ion implantation is less than −60 °C.

In some cases, the temperature for the second ion implantation is a room temperature

In some cases, a maximum value of the second implantation dose is determined by the following steps:
providing a plurality of test semiconductor substrates;
sequentially performing test ion implantation on each of the test semiconductor substrates, where an implantation energy for each test ion implantation is the same as the implantation energy for the first ion implantation, a temperature for each test ion implantation is the same as the temperature for the first ion implantation, an implanted impurity for each test ion implantation is the same as an implanted impurity for the first ion implantation, and implantation doses for each test ion implantation are sequentially increased until a part of the test semiconductor substrates does not generate walking out and a part of the test semiconductor substrates generates walking out; and
using a corresponding maximum implantation dose for a test semiconductor substrate without generated walking out as a maximum value of the second implantation dose.

In some cases, the implanted impurity for the first ion implantation is the same as the implanted impurity for the second ion implantation.

In some cases, the implanted impurity for the first ion implantation includes germanium.

In some cases, the first implantation dose is more than 1E15 cm⁻².

In some cases, the second implantation dose is 50% or less of the first implantation dose.

In some cases, the ion implantation region is located in a source-drain region of a MOS transistor.

In some cases, a back surface of the semiconductor substrate is formed with silicon nitride.

In some cases, a material of the semiconductor substrate includes silicon.

In some cases, the implantation energy for the first ion implantation is more than 25 keV.

In some cases, the implantation energy for the second ion implantation is less than 20 keV.

In this application, the first implantation dose required for the ion implantation region is achieved through two times of ion implantation. The first ion implantation adopts cold ion implantation with a temperature lower than a room temperature. The implantation energy for the first ion implantation is relatively large to achieve definition of the bottom interface of the ion implantation region. Therefore, the impurity distribution morphology of the ion implantation region can be well controlled through the first ion implantation, thereby improving device performance.

In addition, in this application, the second ion implantation is further used. The third implantation dose for the second ion implantation is used to ensure a smaller second implantation dose under a constant first implantation dose. The constant first implantation dose can ensure device performance. A relatively small second implantation dose can reduce an adhesive at a platen of an ion implantation machine, thereby reducing the viscosity of the platen and preventing a walking-out effect on a semiconductor substrate due to an excessively large viscosity of the platen. Therefore, this application can further reduce or prevent walking out, thereby eliminating a defect or a wafer scrapping problem due to walking out.

Since the implantation energy for the second ion implantation is less than the implantation energy for the first ion implantation in this application, the second ion implantation does not affect the morphology of the ion implantation region and does not bring an adverse effect of electric leakage.

### BRIEF DESCRIPTION OF THE DRAWINGS

This application is further described in detail below with reference to the accompanying drawings and specific implementations:

FIG. 1 is a schematic diagram when walking out occurs in an existing cold ion implantation method.

FIG. 2 is a flowchart of an ion implantation method according to an embodiment of this application.

FIG. 3 is a curve of cut-off current (Idoff) and saturation current (Idsat) of NMOS formed by an existing cold ion implantation method and an ion implantation method according to an embodiment of this application.

### DETAILED DESCRIPTION OF THE DISCLOSURE

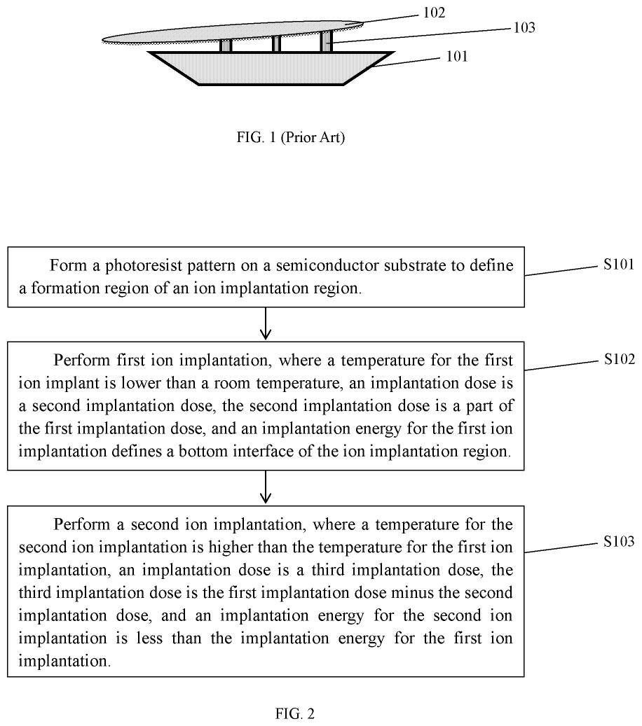

Referring to FIG. 2, FIG. 2 is a flowchart of an ion implantation method according to an embodiment of this application. The ion implantation method according to the embodiment of this application includes the following steps:

Step S101. Form a photoresist pattern on a semiconductor substrate to define a formation region of an ion implantation region, where an implantation dose required for the ion implantation region is a first implantation dose.

In some embodiments, the ion implantation region is located in a source-drain region of a MOS transistor.

A back surface of the semiconductor substrate is formed with silicon nitride.

A material of the semiconductor substrate is silicon. In other embodiments, the material of the semiconductor substrate can also be another suitable material as needed.

Step S101. Perform first ion implantation, where a temperature for the first ion implant is lower than a room temperature, an implantation dose for the first ion implantation is a second implantation dose, the second implantation dose is a part of the first implantation dose, and an implantation energy for the first ion implantation defines a bottom interface of the ion implantation region.

In an embodiment of this application, the first ion implantation is cold ion implantation. The lowest value of the temperature for the first ion implantation is less than −60 °C.

In an embodiment of this application, a maximum value of the second implantation dose is determined by the following steps:

Provide a plurality of test semiconductor substrates.

Sequentially perform test ion implantation on each of the test semiconductor substrates, where an implantation energy for each test ion implantation is the same as the implantation energy for the first ion implantation, a temperature for each test ion implantation is the same as the temperature for the first ion implantation, an implanted impurity for each test ion implantation is the same as an implanted impurity for the first ion implantation, and implantation doses for each test ion implantation are sequentially increased until a part of the test semiconductor substrates does not generate walking out and a part of the test semiconductor substrates generates walking out.

Use a corresponding maximum implantation dose for a test semiconductor substrate without generated walking out as a maximum value of the second implantation dose.

In an embodiment of this application, the implanted impurity for the first ion implantation is germanium. In other embodiments, the implanted impurity for the first ion implantation can also be selected as another impurity as needed.

In other embodiments, the first implantation dose is more than 1E15 cm⁻².

In other embodiments, the second implantation dose is 50% or less of the first implantation dose.

Step S103. Perform a second ion implantation, where a temperature for the second ion implantation is higher than the temperature for the first ion implantation, an implantation dose for the second ion implantation is a third implantation dose, the third implantation dose is the first implantation dose minus the second implantation dose, and an implantation energy for the second ion implantation is less than the implantation energy for the first ion implantation.

In an embodiment of this application, the temperature for the second ion implantation is a room temperature.

The implanted impurity for the first ion implantation is the same as the implanted impurity for the second ion implantation.

In other embodiments, the implantation energy for the first ion implantation is more than 25 keV.

The implantation energy for the second ion implantation is less than 20 keV.

In the embodiments of this application, the first implantation dose required for the ion implantation region is achieved through two times of ion implantation. The first ion implantation uses cold ion implantation with a temperature lower than a room temperature. The implantation energy for the first ion implantation is relatively large to achieve definition of the bottom interface of the ion implantation region. Therefore, the impurity distribution morphology of the ion implantation region can be well controlled through the first ion implantation, thereby improving device performance.

In addition, in the embodiments of this application, the second ion implantation is further used. The third implantation dose for the second ion implantation is used to ensure a smaller second implantation dose under a constant first implantation dose. The constant first implantation dose can ensure device performance. A relatively small second implantation dose can reduce an adhesive at a platen of an ion implantation machine, thereby reducing the viscosity of the platen and preventing a walking-out effect on a semiconductor substrate due to an excessively large viscosity of the platen. Therefore, the embodiments of this application can further reduce or prevent walking out, thereby eliminating a defect or a wafer scrapping problem due to walking out.

Since the implantation energy or the second ion implantation is less than the implantation energy for the first ion implantation in the embodiments of this application, the second ion implantation does not affect the morphology of the ion implantation region and does not bring an adverse effect of electric leakage.

Because the embodiments of this application can reduce or eliminate walking out, times of alarms from an ion implantation machine can be reduced. Therefore, the time required for manual processing due to an alarm from an ion host machine can be saved, especially saving the time during which a shutdown is performed for manually cleaning an ion implantation process cavity of an ion host machine upon wafer scrapping due to breaking. Finally, a normal running time of the ion host machine can be increased, increasing a production capacity and the quantity of fed wafers.

In addition, because the embodiments of this application can reduce defects and walking out, a platen of an ion host machine is not adversely affected by the walking out, thereby reducing the number of replacement times of the platen. The service life of the platen can be increased, thereby reducing costs.

Based on an existing high-energy large-dose cold ion implantation, the embodiments of this application divide ion implantation into high-energy small-dose cold ion implantation and low-energy small-dose normal-temperature ion implantation. The sum of doses for the two times of ion implantation is equal to the dose for the existing cold ion implantation. Since the total dose for the two times of ion implantation remains unchanged and the cold ion implantation has higher implantation energy, the ion implantation region formed in the embodiments of this application has a morphology similar to that of an ion implantation region formed through the existing cold ion implantation. Device performance can be equivalent to that achieved through the existing cold ion implantation. In addition, the embodiments of this application significantly reduce the implantation dose required for cold ion implantation, thereby eliminating machine alarms during cold ion implantation and reducing defects and a yield loss.

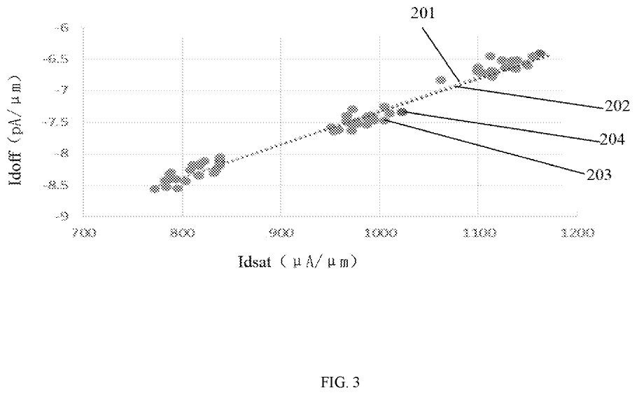

FIG. 3 is a curve of cut-off current and saturation current of NMOS formed by an existing cold ion implantation method and an ion implantation method according to an embodiment of this application. Line 201 is a curve of cut-off current and saturation current of NMOS according to the existing cold ion implantation method. Line 202 is a curve of cut-off current and saturation current of NMOS according to the ion implantation method of an embodiment of this application. It may be seen that lines 201 and 202 are basically coincident, indicating that the performance of the NMOS formed in the embodiments of this application is basically the same as that of the NMOS formed through the existing cold ion implantation method. In FIG. 3, data corresponding to a mark 203 is the data of the cut-off current and saturation current of the NMOS formed through the existing cold ion implantation method, the line 201 is obtained through fitting of the data corresponding to the mark 203, data corresponding to a mark 204 is the data of the cut-off current and saturation current of the NMOS formed through the ion implantation method of an embodiment of this application, and the line 202 is obtained through fitting of the data corresponding to the mark 204.

However, the existing cold ion implantation method requires large-dose implantation under a low temperature, and thus, a problem of frequent walking-out alarms occurs. The method has the following adverse effects:

Defect/Wafer Test (CP) Impact: a defect density (defect DD)>40% affects a yield of a product, and upon server walking out, wafer dropping occurs, causing product scrapping.

Impact on production capacity/wafer feeding: After an alarm, an engineer needs to manually and visually remove wafers with a risk of wafer breaking, which takes about 1 h. After walking out, a shutdown is needed to clean a platen to improve an adhesive situation. Each shutdown takes about 5 hours for cleaning. Currently, an alarm incidence rate is about 5%, meaning one alarm every 20 batches (LOT) for one machine. Calculation is made with an alarm once a day, a shutdown of 6 hours is needed in 24 hours. Therefore, a relatively large impact is caused on a production capacity of an ion implantation machine, finally also affecting wafer feeding.

Impact on a life of a platen: Since the platen has to be replaced after wafer dropping, the life of the platen is reduced. After the existing Cold Ge IMP is used, the life of the platen is only 25% of its original life, significantly increasing costs.

The ion implantation method according to the embodiments of this application completely solves the above problems. To be specific, the embodiments of this application can reduce product defects and improve a product yield and can increase the production capacity of the ion implantation machine and the number of fed wafers, thereby speeding up product circulation and also improving the life of the platen.

The embodiments of this application solve the problems caused by the existing high-energy large-dose cold ion implantation, such as frequent alarms from an implantation machine, serious product defects, and a loss of a product yield caused by wafer dropping and scrapping, while ensuring that performance such as electric properties, a yield, and reliability of a product are not changed.

This application is described in detail above with reference to specific embodiments, but these are not intended to limit this application. Those skilled in the art may make many variations and modifications without departing from the principle of this application. The variations and modifications should also be included in the scope of this application.

What is claimed is:

1. An ion implantation method, comprising steps of:
forming a photoresist pattern on a semiconductor substrate to define a formation region of an ion implantation region, wherein an implantation dose required for the ion implantation region is a first implantation dose;
performing first ion implantation, wherein a temperature for the first ion implant is lower than a room temperature, an implantation dose for the first ion implantation is a second implantation dose, the second implantation dose is a part of the first implantation dose, and an implantation energy for the first ion implantation defines a bottom interface of the ion implantation region; and
performing a second ion implantation, wherein a temperature for the second ion implantation is higher than the temperature for the first ion implantation, an implantation dose for the second ion implantation is a third implantation dose, the third implantation dose is the first implantation dose minus the second implantation dose, and an implantation energy for the second ion implantation is less than the implantation energy for the first ion implantation.

2. The ion implantation method according to claim 1, wherein a lowest value of the temperature for the first ion implantation is less than −60 °C.

3. The ion implantation method according to claim 1, wherein the temperature of the second ion implantation is a room temperature.

4. The ion implantation method according to claim 1, wherein a maximum value of the second implantation dose is determined by the following steps:
providing a plurality of test semiconductor substrates;
sequentially performing test ion implantation on each of the test semiconductor substrates, wherein an implantation energy for each test ion implantation is the same as the implantation energy for the first ion implantation, a temperature for each test ion implantation is the same as the temperature for the first ion implantation, an implanted impurity for each test ion implantation is the same as an implanted impurity for the first ion implantation, and implantation doses for each test ion implantation are sequentially increased until a part of the test semiconductor substrates does not generate walking out and a part of the test semiconductor substrates generates walking out; and
using a corresponding maximum implantation dose for a test semiconductor substrate without generated walking out as a maximum value of the second implantation dose.

5. The ion implantation method according to claim 1, wherein the implanted impurity for the first ion implantation is the same as the implanted impurity for the second ion implantation.

6. The ion implantation method according to claim 5, wherein the implanted impurity for the first ion implantation comprises germanium.

7. The ion implantation method according to claim 6, wherein the first implantation dose is more than 1E15 cm⁻².

8. The ion implantation method according to claim 7, wherein the second implantation dose is 50% or less of the first implantation dose.

9. The ion implantation method according to claim 6, wherein the ion implantation region is located in a source-drain region of a MOS transistor.

10. The ion implantation method according to claim 1, wherein a back surface of the semiconductor substrate is formed with silicon nitride.

11. The ion implantation method according to claim 1, wherein a material of the semiconductor substrate comprises silicon.

12. The ion implantation method according to claim 6, wherein the implantation energy for the first ion implantation is more than 25 keV.

13. The ion implantation method according to claim 12, wherein the implantation energy for the second ion implantation is less than 20 keV.
